(19) United States
(12) Patent Application Publication
(10) Pub. No.: US 2004/0169283 A1
(43) Pub. Date: Sep. 2, 2004

(54) Integrated circuit devices and methods of forming the same that have a low dielectric insulating interlayer between conductive structures

(76) Inventors: Eun-Kyung Baek, Gyeonggi-do (KR); Kyu-Tae Na, Seoul (KR); Joon-Sang Park, Seoul (KR)

Correspondence Address: MYERS BIGEL SIBLEY & SAJOVEC, PO BOX 37428, RALEIGH, NC, 27627, US

(21) Appl. No.: 10/787,996

(22) Filed: Feb. 26, 2004

(30) Foreign Application Priority Data
Feb. 28, 2003 (KR) 2003-12826
Jun. 24, 2003 (KR) 2003-40965

(51) Int. Cl. H01L 23/48

(52) U.S. Cl. 257/760; 438/624

(57) ABSTRACT

An integrated circuit device includes a substrate that has a pair of conductive structures disposed thereon. An insulating interlayer is on the substrate between the pair of conductive structures. The insulating interlayer includes a carbon-containing silicon oxide layer on the substrate and a silicon oxide layer on the carbon-containing silicon oxide layer.

### RELATED APPLICATIONS

This application claims priority to and the benefit of Korean Patent Application No. 10-2003-0012826, filed Feb. 28, 2003 and Korean Patent Application No. 10-2003-0040965, filed Jun. 24, 2003, the disclosures of which are hereby incorporated herein by reference.

### FIELD OF THE INVENTION

The present invention relates to integrated circuit devices and methods of forming the same, and, more particularly, integrated circuit devices having an insulating interlayer between conductive structures and methods of forming the same.

### BACKGROUND OF THE INVENTION

As semiconductor devices have become more highly integrated, various kinds of thin films have been used in the semiconductor devices. For example, when an insulating interlayer is formed between conductive patterns, the insulating interlayer may be a thin film that has a relatively low dielectric constant. When a thin film having a relatively high dielectric constant is formed on a substrate and is used as an insulating interlayer, a parasitic capacitance may be increased and the operating speed of the semiconductor device may be reduced.

Also, as intervals between conductive patterns of a semiconductor device are reduced, a recess between the conductive patterns may be filled with an insulating interlayer that has relatively good gap-filling characteristics so as not to form voids.

A method for forming a thin film that has a relatively low dielectric constant and does not generate voids between conductive patterns has been researched. A carbon-containing silicon oxide layer (SiOC layer) has been used as the thin film because the SiOC layer has a relatively low dielectric constant of about 3.0 and the SiOC layer may be formed in the recess between the conductive patterns so that the parasitic capacitance is reduced.

Despite the relatively low dielectric constant, the use of SiOC as a thin film layer may be restricted in semiconductor fabrication. One reason is that a SiOC layer may be disadvantageous when used in a chemical mechanical polishing (CMP) process. For example, a polishing selectivity between the SiOC layer and a silicon nitride (SiN) insulating interlayer is generally lower than that between a silicon oxide (SiO₂) layer and the SiN layer. When the SiO₂ layer is polished using a slurry, the SiO₂ layer may be fully polished using the SiN layer as a polishing stop layer because the SiO₂ layer has a high polishing selectivity relative to the SiN layer. On the other hand, when the SiOC layer is polished using the slurry, the SiOC layer may not be fully polished using the SiN layer as the polishing stop layer because the SiOC layer has a relatively low polishing selectivity relative to the SiN layer. Also, when a ceria slurry is used, the speed in which an SiOC layer may be polished may be relatively slow. A silica slurry may be used to polish an SiOC layer; however, a polishing endpoint may be difficult to detect. Therefore, although SiOC has a relatively low dielectric constant, SiOC layers may be difficult to use in fabricating semiconductor devices.

Insulating layers may also be formed using a silanol material. In a conventional method, a trench is partially filled with a silanol material and an insulating material is formed in the trench through a high-density plasma process. The silanol material may be formed in a concave shape in the trench, however. Accordingly, when the insulating layer is formed on the silanol material having the concaved shape, the boundary surface between the insulating layer and the silanol material may have an imperfect contact characteristic.

### SUMMARY

According to some embodiments of the present invention, an integrated circuit device comprises a substrate that has a pair of conductive structures disposed thereon. An insulating interlayer is on the substrate between the pair of conductive structures. The insulating interlayer comprises a carbon-containing silicon oxide layer on the substrate and a silicon oxide layer on the carbon-containing silicon oxide layer.

In other embodiments of the present invention, a thickness of the carbon-containing silicon oxide layer as measured from the substrate to an upper surface of the carbon-containing silicon oxide layer is at least 70% of a thickness of the pair of conductive structures as measured from the substrate to respective upper surfaces of the pair of conductive structures.

In still other embodiments of the present invention, a thickness of the silicon oxide layer is about 2000 Å to about 8000 Å.

In still other embodiments of the present invention, the conductive structures respectively comprise a gate structure.

In still other embodiments of the present invention, the conductive structures respectively comprise a metal pattern.

In further embodiments of the present invention, the conductive structures respectively comprise a conductive layer on the substrate and a silicon nitride layer on the conductive layer.

In still further embodiments of the present invention, an upper surface of the carbon-containing silicon oxide layer, opposite the substrate, is above an upper surface of the conductive layer, opposite the substrate.

In still further embodiments of the present invention, the conductive structures further comprise nitride spacers on respective sidewalls of the conductive structures.

In still further embodiments of the present invention, the carbon-containing silicon oxide layer has a dielectric constant less than about 3.0.

In still further embodiments of the present invention, an upper surface of the carbon-containing silicon oxide layer, opposite the substrate, has a concave shape.

Although described above with respect to device embodiments of the present invention, it will be understood that the present invention may also be embodied as methods of forming integrated circuit devices.

### BRIEF DESCRIPTION OF THE DRAWINGS

Other features of the present invention will be more readily understood from the following detailed description of specific embodiments thereof when read in conjunction with the accompanying drawings, in which:

FIGS. 1A-1D are cross sectional views that illustrate integrated circuit devices having a relatively low dielectric insulating interlayer between conductive structures and methods of forming the same in accordance with some embodiments of the present invention; and

FIG. 2 is a timing diagram that illustrates gas flows used in forming integrated circuit devices having a relatively low dielectric insulating interlayer between conductive structures in accordance with some embodiments of the present invention.

### DETAILED DESCRIPTION OF EMBODIMENTS

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like numbers refer to like elements throughout the description of the figures. In the figures, the dimensions of layers and regions are exaggerated for clarity. It will also be understood that when an element, such as a layer, region, or substrate, is referred to as being “on” another element, it can be directly on the other element or intervening elements may be present. In contrast, when an element, such as a layer, region, or substrate, is referred to as being “directly on” another element, there are no intervening elements present.

Methods of forming a thin film in accordance with some embodiments of the present invention will now be described. One or more conductive structures having a recess therebetween are formed on a substrate. The conductive structures may comprise a gate structure and/or a metal pattern. The recess may be a trench or a contact hole. An uppermost layer of the conductive structures may comprise a silicon nitride layer, which may be used as a polishing stop layer.

A methyl-silane based gas and a first hydrogen peroxide gas may be chemically reacted with each other to form a carbon-containing silicon oxide layer on the substrate and the conductive structures. The methyl-silane based gas may comprise CH₃SiH₃ gas and the substrate may be maintained at a temperature of about 0° C. during the chemical reaction.

The thickness of the carbon-containing silicon oxide layer formed on the recess may be thicker than that of the carbon-containing silicon oxide layer formed on sidewalls and upper surfaces of the conductive structures. The carbon-containing silicon oxide layer may flow into the recess so that the recess is filled with the carbon-containing silicon oxide. Accordingly, although the recess may be narrow and deep, the recess may be substantially filled with the carbon-containing silicon oxide layer without voids.

The upper surface of the carbon-containing silicon oxide layer formed in the recess may be lower than that of the conductive structures. An upper surface of the carbon-containing silicon oxide layer formed in the recess may be concave. The thickness of the carbon-containing silicon oxide layer formed in the recess may be about 70% of the depth of the recess or greater in accordance with some embodiments of the present invention. When the conductive structures comprise a conductive layer, the upper surface of the carbon-containing silicon oxide layer formed in the recess may be higher than the upper surface of the conductive layer.

A silicon oxide layer may be formed on the carbon-containing silicon oxide layer using, for example, a silane based gas and a second hydrogen peroxide gas. The silicon oxide layer may have an upper surface that is higher than that of the conductive structures. The silane-based gas may comprise SiH₄ gas. The silicon oxide layer may have a thickness of about 2,000 Å to about 8,000 Å.

The silicon oxide layer may be formed in a chamber using in-situ processing where the carbon-containing silicon oxide layer is formed, which may simplify the processing for forming a thin film. Because the substrate may not be exposed to the outside during formation of the carbon-containing silicon oxide layer and the silicon oxide layer, undesired reaction materials on the boundary surface between the carbon-containing silicon oxide layer and the silicon oxide layer may be reduced. Accordingly, the contact characteristic of the boundary surface between the carbon-containing silicon oxide layer and the silicon oxide layer may be improved. In accordance with further embodiments of the present invention, the carbon-containing silicon oxide layer may be formed using one chamber and the silicon oxide layer may be formed using another chamber.

The silicon oxide layer and the carbon-containing silicon oxide layer may be removed using chemical mechanical polishing (CMP) to expose the upper surface of the conductive structures. Accordingly, a thin film that comprises the carbon-containing silicon oxide layer and a remaining silicon oxide layer may be formed in the recess.

The CMP process may be performed using a slurry that has a relatively high polishing selectivity between a silicon nitride layer and the silicon oxide layer, because the silicon nitride layer may be formed on the conductive structures. The slurry may comprise a ceria slurry in accordance with some embodiments of the present invention. The silicon oxide layer is used as a sacrificial layer when polishing using the ceria slurry; therefore, the polishing speed of the silicon oxide layer is faster than that of the silicon nitride layer. Also, the silicon oxide layer may be planarized during the polishing process using the ceria slurry.

Thus, according to some embodiments of the present invention, a carbon-containing silicon oxide layer is formed in a recess and a silicon oxide layer is formed on the carbon-containing silicon oxide layer and is used as a sacrificial layer during polishing. As a result, parasitic capacitance may be reduced and the polishing speed may be improved. Also, the silicon oxide layer and the carbon-containing silicon oxide layer may be formed in one chamber using in-situ processing so that formation of the insulating interlayer may be simplified.

Methods of forming an insulating interlayer that has a relatively low dielectric constant, in accordance with some embodiments of the present invention, will now be described with reference to the accompanying drawings.

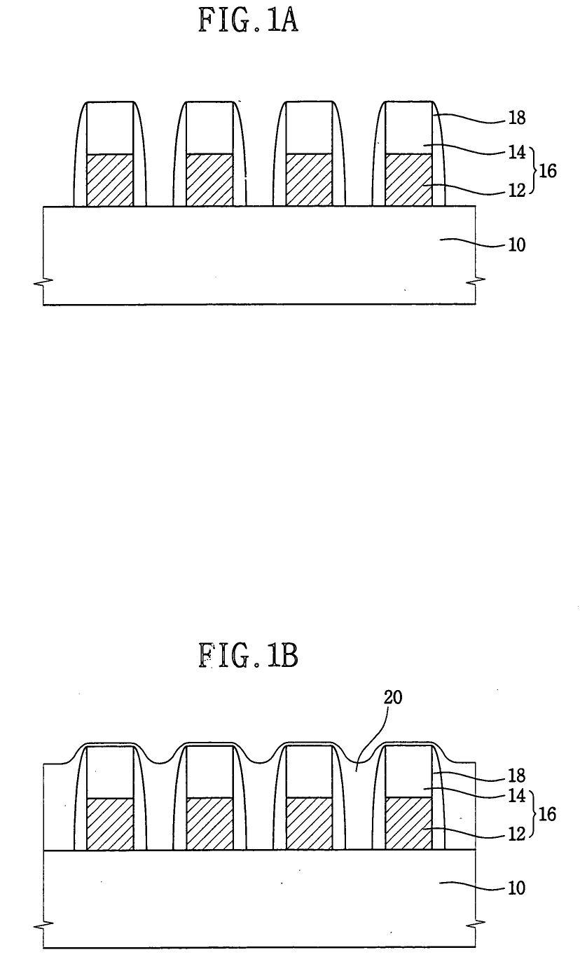

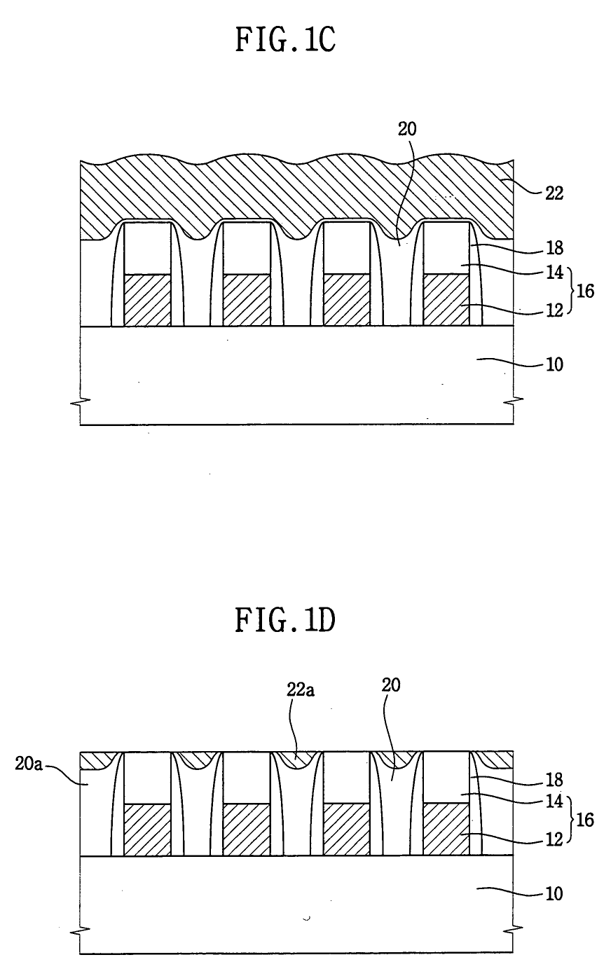

Referring now to FIG. 1A, conductive structures 16 are formed on a substrate 10. The conductive structures 16 comprise a conductive pattern 12 and a hard mask pattern 14, which is formed on the conductive pattern 12. A conductive layer (not shown) and a hard mask layer (not shown) are successively formed on the substrate 10. The hard mask layer may comprise a silicon nitride layer that has a polishing selectivity relative to a silicon oxide layer. The hard mask layer may be patterned through a photolithography process to form the hard mask pattern 14. The conductive layer may be etched using the hard mask pattern 14 as an etching mask to form the conductive pattern 12. The conductive pattern 12 may comprise wiring, such as a bit line or a gate electrode of a transistor. Also, the conductive pattern 12 may comprise a metal material or a polysilicon material doped with an impurity. The hard mask pattern 14 may be used as a polishing stop layer in a successive CMP process.

Silicon nitride may be deposited on the conductive structures 16 and the substrate 10. The silicon nitride is anisotropically etched to form a nitride spacer 18 on the sidewalls of the conductive structures 16. The gap between the conductive structures is reduced due to the nitride spacer 18.

Referring to FIG. 1B, a methyl-silane based gas and a hydrogen peroxide gas may be reacted with each other to form a carbon-containing silicon oxide layer 20 on the substrate 10. A recess formed between the conductive structures 16 is filled with the carbon-containing silicon oxide layer 20. As shown in FIG. 1B, the carbon-containing silicon oxide layer 20 has a concaved surface located in the recess.

The resulting structure is loaded into a deposition chamber. In accordance with some embodiments of the present invention, the deposition chamber has a pressure of about 1,000 mTorr and a shower head for providing reaction gases to the deposition chamber has a temperature of about 100° C. The substrate 10 may have a temperature of about 0° C. The methyl-silane based gas is provided to the deposition chamber at a flux of about 70 sccm to about 100 sccm. The hydrogen peroxide gas is provided to the deposition chamber at a flux of about 0.5 g/min to about 1 g/min.

The carbon-containing silicon oxide layer 20 may have a relatively low dielectric constant of about 3.0 or less. When the recess is filled with the carbon-containing silicon oxide layer 20, the parasite capacitance may be reduced. In accordance with some embodiments of the present invention, the upper surface of the carbon-containing silicon oxide layer 20 is higher than that of the conductive pattern 12. Also, the thickness of the carbon-containing silicon oxide layer 20 formed in the recess may be at least about 70% of the depth of the recess.

When the deposition process is performed using the hydrogen peroxide gas, the recess is filled in advance with the carbon-containing silicon oxide layer 20. The thickness of the carbon-containing silicon oxide layer 20 formed in the recess is thicker than that of the carbon-containing silicon oxide layer 20 formed on the conductive structures 16. Although the recess may be relatively narrow and deep, the recess may be filled with the carbon-containing silicon oxide layer 20 without voids.

Referring to FIG. 1C, a silane based gas and a second hydrogen peroxide gas are provided into the deposition chamber to form a silicon oxide layer 22 on the carbon-containing silicon oxide layer 20. The silicon oxide layer 22 may have a relatively high dielectric constant compared to the carbon-containing silicon oxide layer 20. The characteristics of the silicon oxide layer 22 are similar to that of a silicon oxide layer formed through a chemical vapor deposition process not using the hydrogen peroxide gas.

The deposition chamber has a pressure approximately equal to or less than the pressure used when the carbon-containing silicon oxide layer 20 is formed. For example, the deposition chamber may have a pressure of about 850 mTorr. The shower head may be at a temperature of about 100° C. The substrate 10 may have a temperature of about 0° C. The silane-based gas may be provided to the deposition chamber at a flux of about 100 sccm to about 140 sccm. The hydrogen peroxide gas may be provided to the deposition chamber at a flux of about 0.5 g/min to about 1 g/min. The hydrogen peroxide gas may be provided to the deposition chamber at approximately the same flux or less than that used when the carbon-containing silicon oxide layer 20 is formed.

The silicon oxide layer 22 has an upper surface that is higher than that of the conductive structures 16. The concaved portion of the carbon-containing silicon oxide layer 20 is filled with the silicon oxide layer 22. The silicon oxide layer 22 formed on the concaved portion of the carbon-containing silicon oxide layer 20 has a thickness that is greater than that of the silicon oxide layer 22 formed on the conductive structures 16. As a result, the silicon oxide layer 22 has a relatively flat upper surface.

The silicon oxide layer 22 may serve as a sacrificial layer that has a polishing selectivity relative to the silicon nitride layer. The sacrificial layer may allow for an increase in polishing speed. The silicon oxide layer 22 may have a thickness of about 2,000 Å to about 8,000 Å. The silicon oxide layer 22 and the carbon-containing silicon oxide layer may be formed in one deposition chamber using an in-situ process.

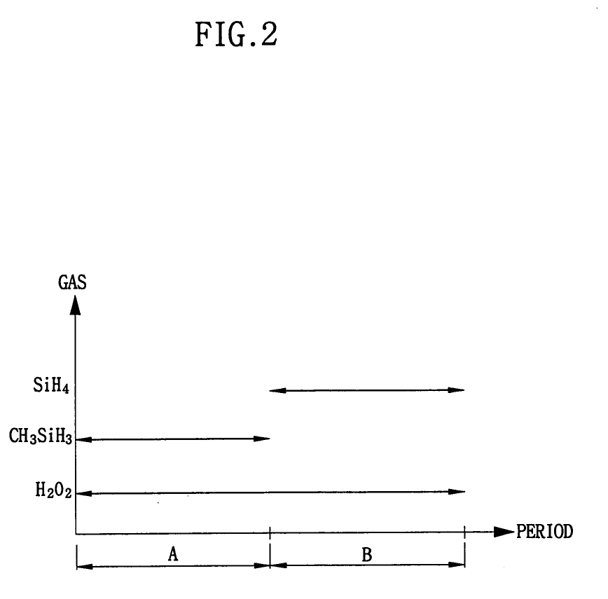

FIG. 2 is a timing diagram that illustrates gas flows when the silicon oxide layer and the carbon-containing silicon oxide layer are formed using an in-situ process in accordance with some embodiments of the present invention. Referring now to FIG. 2, during time period A, the CH₃SiH₃ gas and the H₂O₂ gas are reacted with each other to form the carbon-containing silicon oxide layer 20 in the recess. During time period B, the SiH₄ gas and the H₂O₂ gas are reacted with each other to form the silicon oxide layer 22 on the carbon-containing silicon oxide layer 20.

The carbon-containing silicon oxide layer 20 and the silicon oxide layer 22 are formed using an in-situ process by providing the different gases to one deposition chamber, which may simplify the process for forming a thin film. Because the substrate 10 may not be exposed to the outside during formation of the carbon-containing silicon oxide layer 20 and the silicon oxide layer 22, undesired reaction materials on the boundary surface between the carbon-containing silicon oxide layer 20 and the silicon oxide layer 22 may be reduced. Accordingly, the contact characteristic of the boundary surface between the carbon-containing silicon oxide layer 20 and the silicon oxide layer 22 may be improved.

Referring to FIG. 1D, the silicon oxide layer 22 is polished to expose the upper surface of the conductive structures 16. As a result, the recess between the conductive structures 16 is filled with an insulating interlayer that comprises the carbon-containing silicon oxide layer 20 and the remaining silicon oxide layer 22a. The CMP process may be performed using a ceria slurry. The silicon oxide layer 22 may have relatively high polishing selectivity relative to the carbon-containing silicon oxide layer 20 with respect to the ceria slurry. When a ceria slurry is used, the silicon oxide layer 22 may be fully polished through the CMP process. Because the polishing is obstructed by the hard mask pattern 14, the insulating interlayer may be planarized.

Thus, according to some embodiments of the present invention, the recess between the conductive structures 16 is filled with the carbon-containing silicon oxide layer 20, which has a relatively low dielectric constant, without forming voids. Therefore, the parasitic capacitance generated between the conductive structures 16 may be reduced so that the response speed of the semiconductor device may be improved. Also, because the silicon oxide layer 22 may be formed on the carbon-containing silicon oxide layer 20 as a sacrificial layer using an in-situ process, the CMP process may be performed in a relatively stable manner to the polishing endpoint.

### EXAMPLE 1

A carbon-containing silicon oxide layer was formed on the substrate under the conditions of Table 1.

TABLE 1

| Pressure of | Temperature of | Temperature of | Flux of | Flux of |
|---|---|---|---|---|
| chamber | shower head | substrate | CH₃SiH₃ gas | H₂O₂ gas |
| 1,000 mTorr | 100° C. | 0° C. | 85 sccm | 0.75 g/min |

The carbon-containing silicon oxide layer was polished using a ceria slurry having a polishing selectivity between the nitride layer and the oxide layer. The carbon-containing silicon oxide layer was polished at a speed of about 700 Å/min.

In another experiment, the carbon-containing silicon oxide layer was polished using a silica slurry that does not have a polishing selectivity between the nitride layer and the oxide layer. In this experiment, the carbon-containing silicon oxide layer was polished at a speed of about 1,900 Å/min.

In the above experiments, it was discovered that the polishing speed of the carbon-containing silicon oxide layer using the ceria slurry was slower than that of the carbon-containing silicon oxide layer using the silica slurry. Based on this result, it was determined that the carbon-containing silicon oxide layer is less desirable for use as a polishing sacrificial layer.

### EXAMPLE 2

A silicon oxide layer was formed on the substrate under the conditions of Table 2.

TABLE 2

| | | | Flux of | |
|---|---|---|---|---|
| Pressure of | Temperature of | Temperature of | CH₃SiH₃ | Flux |
| chamber | shower head | substrate | gas | of H₂O₂ gas |
| 850 mTorr | 100° C. | 0° C. | 120 sccm | 0.65 g/min |

The silicon oxide layer was polished using a ceria slurry having the polishing selectivity between the nitride layer and the oxide layer. The silicon oxide layer was polished at a speed of about 1,829 Å/min.

In another experiment, the silicon oxide layer was polished using a silica slurry that does not have a polishing selectivity between the nitride layer and the oxide layer. In this experiment, the silicon oxide layer was polished at a speed of about 1,802 Å/min.

In the above experiments, it was discovered that the polishing speed of the silicon oxide layer using the silica slurry was a little slower than that of the silicon oxide layer using the ceria slurry. Based on this result, it was determined that the silicon oxide layer may be used as a polishing sacrificial layer.

### EXAMPLE 3

After the experiments of Examples 1 and 2 were performed, the polished thickness of the silicon oxide layer and the carbon-containing silicon oxide layer were measured. When the silicon oxide layer was polished using the ceria slurry, the polished thickness of the silicon oxide layer was about 197 Å. When the carbon-containing silicon oxide layer was polished using the ceria slurry, the polished thickness of the carbon-containing silicon oxide layer was about 580 Å. When the carbon-containing silicon oxide layer was polished using the silica slurry, the polishing speed of the carbon-containing silicon oxide layer was generally satisfactory. The polished thickness of the carbon-containing silicon oxide layer was relatively thick, however. Therefore, the carbon-containing silicon oxide layer is generally less desirable for use as the sacrificial layer.

On the other hand, when the silicon oxide layer was polished using the ceria slurry, the polished thickness of the silicon oxide layer was thinner than that of the carbon-containing silicon oxide. Therefore, a relatively uniform thin film may be obtained when silicon oxide is used to form the sacrificial layer. Thus, according to some embodiments of the invention, after the carbon-containing silicon oxide layer, which has a relatively low dielectric constant, is formed on the substrate, the silicon oxide layer, which has a standard dielectric constant, is formed on the carbon-containing silicon oxide layer and is used as a sacrificial layer.

In concluding the detailed description, it should be noted that many variations and modifications can be made to the preferred embodiments without substantially departing from the principles of the present invention. All such variations and modifications are intended to be included herein within the scope of the present invention, as set forth in the following claims.

That which is claimed:

1. An integrated circuit device, comprising:
a substrate;
a pair of conductive structures on the substrate; and
an insulating interlayer on the substrate between the pair of conductive structures, the insulating interlayer including a carbon-containing silicon oxide layer on the substrate and a silicon oxide layer on the carbon-containing silicon oxide layer.

2. The integrated circuit device of claim 1, wherein a thickness of the carbon-containing silicon oxide layer as measured from the substrate to an upper surface of the carbon-containing silicon oxide layer is at least 70% of a thickness of the pair of conductive structures as measured from the substrate to respective upper surfaces of the pair of conductive structures.

3. The integrated circuit device of claim 1, wherein a thickness of the silicon oxide layer is about 2000 Å to about 8000 Å.

4. The integrated circuit device of claim 1, wherein the conductive structures include a gate structure, respectively.

5. The integrated circuit device of claim 1, wherein the conductive structures include a metal pattern, respectively.

6. The integrated circuit device of claim 1, wherein the conductive structures respectively comprise:
a conductive layer on the substrate; and
a silicon nitride layer on the conductive layer.

7. The integrated circuit device of claim 1, wherein an upper surface of the carbon-containing silicon oxide layer, opposite the substrate, is above an upper surface of the conductive layer, opposite the substrate.

8. The integrated circuit device of claim 1, wherein the conductive structures further comprise:
nitride spacers on respective sidewalls of the conductive structures.

9. The integrated circuit device of claim 1, wherein the carbon-containing silicon oxide layer has a dielectric constant less than about 3.0.

10. The integrated circuit device of claim 1, wherein an upper surface of the carbon-containing silicon oxide layer, opposite the substrate, has a concave shape.

11. A method of forming an integrated circuit device, comprising:
providing a substrate;
forming a pair of conductive structures on the substrate;
forming a carbon-containing silicon oxide layer on the substrate between the pair of conductive structures; and
forming a silicon oxide layer on the carbon-containing silicon oxide layer.

12. The method of claim 11, wherein forming the carbon-containing silicon oxide layer comprises:
reacting a methyl-silane based gas and a hydrogen peroxide gas in a deposition chamber.

13. The method of claim 12, wherein the deposition chamber comprises a shower head for providing reaction gases to the deposition chamber, the deposition chamber having a pressure of about 1000 mTorr and the shower head having a temperature of about 100° C.

14. The method of claim 13, wherein the substrate has a temperature of about 0° C.

15. The method of claim 12, wherein reacting the methyl-silane based gas and the hydrogen peroxide gas comprises:
providing the methyl-silane based gas to the deposition chamber at a flux of about 70 sccm to about 100 sccm; and
providing the hydrogen peroxide gas to the deposition chamber at a flux of about 0.5 g/min to about 1 g/min.

16. The method of claim 11, wherein forming the silicon oxide layer comprises:
reacting a silane based gas and a hydrogen peroxide gas in a deposition chamber.

17. The method of claim 16, wherein the deposition chamber comprises a shower head for providing reaction gases to the deposition chamber, the deposition chamber having a pressure of about 850 mTorr and the shower head having a temperature of about 100° C.

18 The method of claim 17, wherein the substrate has a temperature of about 0° C.

19. The method of claim 16, wherein reacting the silane based gas and the hydrogen peroxide gas comprises:
providing the silane based gas to the deposition chamber at a flux of about 100 sccm to about 140 sccm; and
providing the hydrogen peroxide gas to the deposition chamber at a flux of about 0.5 g/min to about 1 g/min.

20. The method of claim 11, wherein forming the carbon-containing silicon oxide layer and forming the silicon oxide layer comprises:
forming the carbon-containing silicon oxide layer in a deposition chamber; and
forming the silicon oxide layer in the deposition chamber.

21. The method of claim 11, wherein forming the silicon oxide layer on the carbon-containing silicon oxide layer comprises:
polishing the silicon oxide layer to expose an upper surface of at least one of the pair of conductive structures, opposite the substrate.

22. The method of claim 11, wherein polishing the silicon oxide layer comprises:
chemical mechanical polishing the silicon oxide layer using a ceria slurry.

23. The method of claim 11, further comprising:
forming nitride spacers on respective sidewalls of the conductive structures.

24. A method for forming a thin film of a semiconductor device comprising:
forming a carbon-containing silicon oxide layer on a substrate and on conductive structures formed on the substrate using a methyl-silane based gas and a first hydrogen peroxide gas to fill a recess between the conductive structures with the carbon-containing silicon oxide layer;
forming a silicon oxide layer on the carbon-containing silicon oxide layer using a silane based gas and a second hydrogen peroxide gas, wherein the silicon oxide layer has an upper surface higher than that of the conductive structures; and
polishing the silicon oxide layer and the carbon-containing silicon oxide layer to expose the upper surface of the conductive structures.

25. The method of claim 24, wherein an uppermost layer of the conductive structures includes a silicon nitride layer.

26. The method of claim 24, wherein the carbon-containing silicon oxide layer and the silicon oxide layer are formed through an in-situ process.

27. The method of claim 24, wherein the silicon oxide layer has a thickness of about 2,000 Åto about 8,000 Å.

28. The method of claim 24, wherein the silicon oxide layer is polished through a chemical mechanical polishing process using a ceria slurry.

29. The method of claim 24, wherein the carbon-containing silicon oxide layer formed in the recess has a thickness corresponding to at least about 70% of a depth of the recess.

30. A method for forming an insulating interlayer of a semiconductor device comprising:
forming conductive structures having a conductive layer pattern and a nitride layer pattern on a substrate to form a recess between the conductive structures;
forming a carbon-containing silicon oxide layer on the substrate and the conductive structures using a methyl-silane based gas and a first hydrogen peroxide gas to fill the recess with the carbon-containing silicon oxide layer;
forming a silicon oxide layer on the carbon-containing silicon oxide layer using a silane based gas and a second hydrogen peroxide gas, wherein the silicon oxide layer has an upper surface higher than that of the conductive structures; and
polishing the silicon oxide layer and the carbon-containing silicon oxide layer until the upper surface of the conductive structures is exposed to form an insulating interlayer comprising the carbon-containing silicon oxide layer and a remaining silicon oxide layer in the recess.

31. The method of claim 30, wherein the conductive layer pattern comprises a gate line or a bit line.

32. The method of claim 30, wherein the carbon-containing silicon oxide layer and the silicon oxide layer are formed through an in-situ process.

33. The method of claim 30, wherein an upper surface of the carbon-containing silicon oxide layer formed in the recess is higher than that of the conductive layer pattern.

34. The method of claim 30, wherein the carbon-containing silicon oxide layer formed in the recess has a thickness of at least about 70% of a depth of the recess.

35. The method of claim 30, wherein the silicon oxide layer has a thickness of about 2,000 Å to about 8,000 Å.

36. The method of claim 30, wherein the silicon oxide layer is polished through a chemical mechanical polishing process using a ceria slurry, the ceria slurry having a polishing selectivity between the silicon oxide layer and the nitride layer pattern.

37. The method of claim 30, further comprising forming nitride spacers on sidewalls of the conductive structures.

38. A method for forming an insulating interlayer of a semiconductor device comprising:
forming conductive structures having a conductive layer pattern and a nitride layer pattern on a substrate to form a recess between the conductive structures;
reacting a methyl-silane based gas with a first hydrogen peroxide gas over the conductive structures to form a carbon-containing silicon oxide layer on the substrate and the conductive structures, wherein the recess is filled with the carbon-containing silicon oxide layer;
reacting a silane based gas with a second hydrogen peroxide gas to form a silicon oxide layer on the carbon-containing silicon oxide layer, wherein the silicon oxide layer has an upper surface higher than that of the conductive structures; and
polishing the silicon oxide layer and the carbon-containing silicon oxide layer until the upper surface of the structures is exposed to form an insulating interlayer having the carbon-containing silicon oxide layer and a remaining silicon oxide layer in the recess.

39. The method of claim 38, wherein an upper surface of the carbon-containing silicon oxide layer formed in the recess is higher than that of the conductive layer pattern.

40. The method of claim 38, wherein the silicon oxide layer has a thickness of about 2,000 Å to about 8,000 Å.

41. The method of claim 38, wherein the silicon oxide layer is polished through a chemical mechanical polishing process using a ceria slurry, the ceria slurry having a polishing selectivity between the silicon oxide layer and the silicon nitride pattern.

42. A method for planarizing a semiconductor device comprising:
loading a substrate having conductive patterns into a chamber, wherein the conductive patterns include a conductive layer and a silicon nitride layer that form a recess therebetween;
reacting a methyl-silane based gas with a first hydrogen peroxide gas in the chamber to form a carbon-containing silicon oxide layer on the substrate and the conductive patterns, wherein the recess is filled with the carbon-containing silicon oxide layer;
reacting a silane based gas with a second hydrogen peroxide gas to form a silicon oxide layer on the carbon-containing silicon oxide layer; and
polishing the silicon oxide layer through a chemical mechanical polishing process using a slurry, wherein the slurry has a polishing selectivity between the silicon oxide layer and the silicon nitride layer.

43. The method of claim 42, wherein the conductive patterns comprise a gate line or a bit line.

44. The method of claim 42, wherein an upper surface of the carbon-containing silicon oxide layer formed in the recess is higher than that of the conductive layer pattern.

45. The method of claim 42, wherein the silicon oxide layer has a thickness of about 2,000 Å to about 8,000 Å.
